(19) United States
(12) Patent Application Publication
(10) Pub. No.: US 2014/0062521 A1
(43) Pub. Date: Mar. 6, 2014

(54) WIRING DEFECT INSPECTING METHOD, WIRING DEFECT INSPECTING APPARATUS, AND METHOD FOR MANUFACTURING SEMICONDUCTOR SUBSTRATE

(71) Applicant: Eiji Yamada, Osaka-shi (JP)

(72) Inventor: Eiji Yamada, Osaka-shi (JP)

(73) Assignee: SHARP KABUSHIKI KAISHA, Osaka-shi, Osaka (JP)

(21) Appl. No.: 14/113,462

(22) PCT Filed: Apr. 25, 2012
(86) PCT No.: PCT/JP2012/061117

§ 371 Date: Oct. 23, 2013

(30) Foreign Application Priority Data
Apr. 25, 2011 (JP) 2011-097531

(51) Int. Cl. G01R 31/26; G01R 31/02

(52) U.S. Cl. CPC G01R 31/26; G01R 31/025
USPC 324/762.01

(57) ABSTRACT

A wiring defect inspecting method in accordance with the present invention comprises: obtaining a resistance of a short-circuited path of a semiconductor substrate; applying a voltage, which is specified on the basis of the resistance obtained, to the semiconductor substrate having a defect portion so as to cause the defect portion to generate heat; and capturing, with use of an infrared camera, an image of the semiconductor substrate whose temperature has increased due to the heat generated from the defect portion.

### TECHNICAL FIELD

The present invention relates to a wiring defect inspecting method and a wiring defect inspecting apparatus, each of which is suitable for detecting a defect in wiring provided on a semiconductor substrate such as a liquid crystal panel or a solar panel, and a method for manufacturing the semiconductor substrate.

### BACKGROUND ART

A manufacturing process of a liquid crystal panel, which is one of examples of a semiconductor substrate, is roughly made up of an array (TFT) step, a cell (liquid crystal) step, and a module step. In the array step, a gate electrode, a semiconductor film, a source electrode, a drain electrode, a protective film, and a transparent electrode are formed on a transparent substrate, and then array inspection is carried out so as to inspect whether or not wiring such as an electrode, a wiring, or the like is short-circuited.

Normally, in array inspection, such defects are identified by measuring (i) an electric resistance between both ends of a wiring or (ii) an electric resistance and an electric capacitance between adjacent wirings by bringing probes into contact with ends of the wiring(s). However, even if the presence of a defect in a wiring section is detected, it is not easy to identify a position of the defect in the array inspection.

For example, methods for improving the above problem to thereby identify the position of the defect include infrared inspection in which a voltage is applied to a leak defect substrate so as to cause the leak defect substrate to generate heat, and a position of a defect is identified with use of an image, captured by an infrared camera, of a surface temperature of the leak defect substrate.

Patent Literature 1 relates to infrared inspection for detecting a short circuit defect of a substrate with use of an infrared image. According to the infrared inspection of Patent Literature 1, by using a difference image between infrared images of the substrate, respectively captured before and after voltage application, it is possible to detect a position of a wiring that is generating heat, and thus identify a position of the defect.

### CITATION LIST

### Patent Literatures

Patent Literature 1

Japanese Patent Application Publication, Tokukaihei, No. 6-207914 A (Publication Date: Jul. 26, 1994)

### SUMMARY OF INVENTION

### Technical Problem

However, Patent Literature 1 describes as follows. When the technique of Patent Literature 1 is used, only a drawing section fails to be detected in a case where the voltage applied to the leak defect substrate is small. On the other hand, in a case where the voltage is increased so that wirings can also be detected, there is a possibility that the voltage is increased excessively, thereby causing a pixel having a short-circuiting to be burned and cut off or causing a normal thin-film transistor to be damaged. Patent Literature states that it is therefore necessary to increase the voltage gradually. However, in order to increase the voltage gradually, a long process time is required. As a matter of course, this increases inspection time required per leak defect substrate, and thus prevents enhancing inspection performance per unit time.

Further, in a case where the voltage to be applied is gradually increased, a time period from a point when the voltage application is started to a point when the voltage application is finished is increased. This means an increase in heat generation time during which a heat-generating part generates heat. The heat is conducted from the heat-generating part toward a peripheral part by thermal conduction. As a result, a temperature of the peripheral part, which is not actually generating heat, increases. In a case where an infrared image is captured under this circumstance, a part that is not actually generating heat is detected, by mistake, as being a heat-generating part. This makes it difficult to detect a heat-generating path accurately, or makes a contour of heat-generating part unclear to thereby make it difficult to recognize a wiring that extends from the heat-generating part.

Further, according to the technique, it is not easy to detect a leak defect portion stably. This is because an increase in temperature (amount of generated heat) varies in accordance with a type of the leak defect substrate, a short-circuited portion (location on the leak defect substrate), or a resistance of the short-circuited portion itself. In a case where the type of the leak defect substrate varies, an electric resistivity, a line width, and a film thickness of a wiring vary. This causes variation in temperature increase (amount of generated heat). Further, wirings on the substrate are not all identical, and a line width and a film thickness of a wiring varies depending on the location. Accordingly, the temperature increase (amount of generated heat) varies depending on the short-circuited portion (location on the substrate). A short-circuiting is caused by various factors such as a conductive foreign body that has accidentally mixed in during manufacture of the substrate, a remaining film from a step of forming a wiring layer, an electrostatic discharge failure, or the like. As such, an electric resistance of a short-circuited portion itself significantly varies every time a short-circuiting occurs. This causes variation in temperature increase (amount of generated heat).

Therefore, application of the same voltage to any leak defect substrates will result in variation in temperature increase (amount of generated heat) due to the above reasons. This makes it difficult to stably detect a leak defect portion that generates heat.

The present invention is accomplished in view of the above problems. An object of the present invention is to provide: a method and an apparatus each of which allows stable identification of a leak defect portion in infrared inspection by applying, to a short-circuited path on a leak defect substrate, a voltage specified based on a resistance measured in advance by resistance inspection, so that an amount of heat generated from the short-circuited path on the leak defect substrate becomes constant regardless of a type of the leak defect substrate, the short-circuited portion (location on the leak defect substrate), a resistance of the short-circuited portion itself, or the like; and a method for manufacturing a semiconductor substrate.

### Solution to Problem

In order to achieve the object, a wiring defect inspecting method in accordance with the present invention a wiring defect inspecting method including the steps of: (a) measuring a resistance of wiring included in a semiconductor substrate, thereby determining whether or not the semiconductor substrate has a wiring short-circuited part; (b) causing a short-circuited path to generate heat by applying, to the short-circuited path, a voltage specified on the basis of the resistance measured in the step (a), the short-circuited path including the wiring short-circuited part of the semiconductor substrate which has been determined to have the wiring short-circuited part in the step (a); and (c) capturing, with use of an infrared camera, an image of the short-circuited path which has generated heat in the step (b) and identifying a position of the wiring short-circuited part on the basis of information of the image.

According to the above arrangement, the voltage specified on the basis of the resistance obtained in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, in order to attain the object, a wiring defect inspecting apparatus in accordance with the present invention is a wiring defect inspecting apparatus including: a data taking-in section for taking in a resistance of wiring included in a semiconductor substrate, the resistance being measured in advance; a voltage applying section for applying a voltage to the wiring; a control section for controlling the voltage applying section; and an infrared camera for detecting infrared rays emitted from the semiconductor substrate which is generating heat in response to the voltage applied under control of the control section, the control section controlling, in accordance with the resistance taken in by the data taking-in section, a value of the voltage applied for causing the wiring to generate heat.

According to the above arrangement, the voltage specified on the basis of the resistance of the wiring measured in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, since resistance measurement is carried out in a different apparatus, the resistance measurement and the image capturing by the infrared camera can be operated in parallel with each other, so that the performance can be improved.

Further, in order to attain the object, another wiring defect inspecting apparatus in accordance with the present invention is a wiring defect inspecting apparatus including: a voltage applying section for applying a voltage to wiring included in a semiconductor substrate; a resistance measuring section for measuring a resistance of the wiring; a control section for controlling the voltage applying section; and an infrared camera for detecting infrared rays emitted from the semiconductor substrate which is generating heat in response to the voltage applied under control of the control section, the control section controlling, in accordance with the resistance measured by the resistance measuring section, a value of the voltage applied for causing the wiring to generate heat.

According to the above arrangement, the voltage specified on the basis of the resistance obtained in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, since the wiring defect inspecting apparatus itself measures the resistance of the wiring, it is not necessary to separately provide an apparatus for measuring resistance. This allows a reduction in the number of apparatuses.

Further, a method, in accordance with the present invention, for manufacturing a semiconductor substrate is a method for manufacturing a semiconductor substrate, including the steps of: (a) forming, on a substrate, (i) at least one of a gate electrode, a source electrode, and a drain electrode, (ii) wiring connected to the at least one of the gate electrode, the source electrode, and the drain electrode, and (iii) a semiconductor film, thereby forming a semiconductor substrate on which the wiring is provided; (b) measuring a resistance of the wiring included in the semiconductor substrate, thereby determining whether or not the semiconductor substrate has a wiring short-circuited part; (c) causing a short-circuited path to generate heat by applying, to the short-circuited path, a voltage specified on the basis of the resistance measured in the step (b), the short-circuited path including the wiring short-circuited part of the semiconductor substrate which has been determined to have the wiring short-circuited part in the step (b); and (d) capturing, with use of an infrared camera, an image of the short-circuited path which has generated heat in the step (c) and identifying a position of the wiring short-circuited part on the basis of information of the image.

### Advantageous Effects of Invention

As described above, according to a wiring defect inspecting method in accordance with the present invention and a wiring defect inspecting apparatus in accordance with the present invention, a voltage specified on the basis of a resistance obtained in advance by resistance inspection is applied to a semiconductor substrate (leak defect substrate). This makes an amount of heat generated from the semiconductor substrate (leak defect substrate) constant. Accordingly, an increase in temperature can be reliably checked by infrared inspection with use of an infrared camera, so that a short-circuited part can be identified. Further, the defect part is prevented from being burned and cut off due to application of too high a voltage. This allows the short-circuited part to be identified stably.

### BRIEF DESCRIPTION OF DRAWINGS

FIG. 1 shows (i) a block diagram illustrating an arrangement of a wiring defect inspecting apparatus in accordance with an embodiment of the present invention and (ii) a perspective view illustrating an arrangement of a motherboard having liquid crystal panels.

FIG. 2 is a perspective view illustrating an arrangement of the wiring defect inspecting apparatus.

FIG. 3 is a plan view of a liquid crystal panel and a probe section which are used in an embodiment of the present invention.

FIG. 4 is a flowchart showing a wiring defect inspecting method in accordance with an embodiment of the present invention.

FIG. 5 is a schematic view illustrating a defect of a pixel section used in an embodiment of the present invention.

FIG. 6 is a schematic view illustrating a short-circuited path used in an embodiment of the present invention.

### DESCRIPTION OF EMBODIMENTS

### Embodiment 1

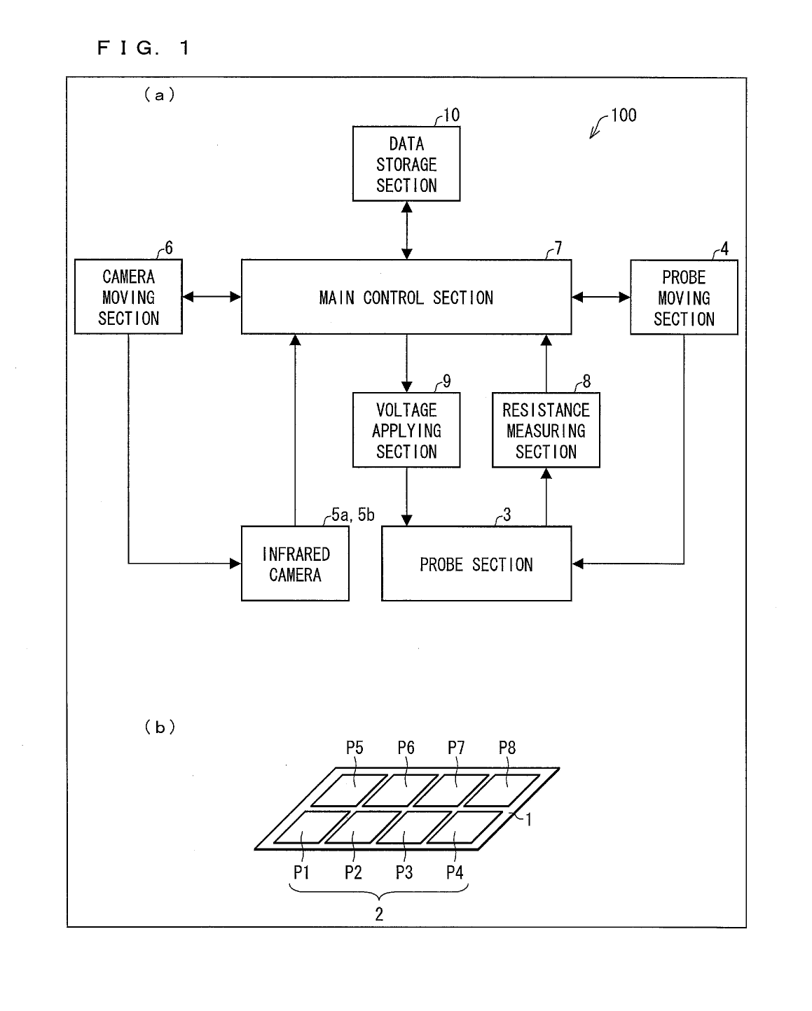

An embodiment of a wiring defect inspecting method in accordance with the present invention is described with reference to FIGS. 1 through 5.

(a) of FIG. 1 is a block diagram illustrating an arrangement of a wiring defect inspecting apparatus 100 for carrying out a wiring defect inspecting method in the present embodiment. (b) of FIG. 1 is a perspective view of a motherboard 1 (semiconductor substrate) to be subjected to wiring defect inspection with use of the wiring defect inspecting apparatus 100.

The wiring defect inspecting apparatus 100 is capable of inspecting a defect of wiring or the like of a plurality of liquid crystal panels 2 (semiconductor substrates) provided on the motherboard 1 illustrated in (b) of FIG. 1. For this purpose, the wiring defect inspecting apparatus 100 includes (i) a probe section 3 to be conductive with the liquid crystal panels 2, and (ii) a probe moving section 4 for moving the probe section 3 to a position above each of the liquid crystal panels 2. The wiring defect inspecting apparatus 100 further includes an infrared camera 5 for obtaining an infrared image, and a camera moving section 6 for moving the infrared camera 5 above the liquid crystal panels 2. Further, the wiring defect inspecting apparatus 100 includes a main control section 7 (control section) for controlling the probe moving section 4 and the camera moving section 6.

The probe section 3 is connected to (i) a resistance measuring section 8 for measuring a resistance between wirings of a liquid crystal panel 2, and a voltage applying section 9 for applying a voltage between wirings of the liquid crystal panel 2. The resistance measuring section 8 and the voltage applying section 9 are controlled by the main control section 7.

The main control section 7 is connected to a data storage section 10 for storing a resistance between wirings and image data.

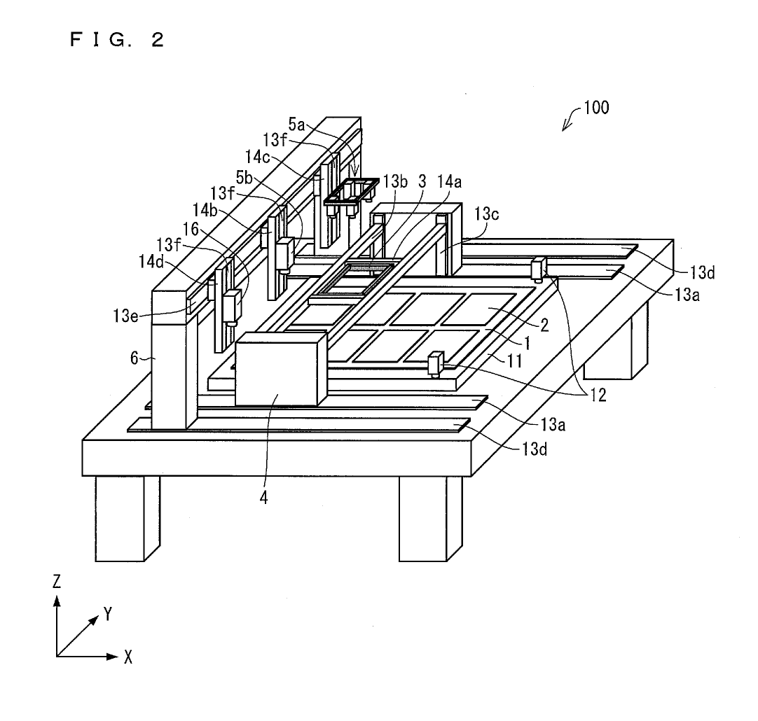

FIG. 2 is a perspective view illustrating an arrangement of the wiring defect inspecting apparatus 100 in the present embodiment. As illustrated in FIG. 2, the wiring defect inspecting apparatus 100 includes a base and an alignment stage 11 which is provided on a base and on which the motherboard 1 can be placed. A position of the alignment stage 11 on which the motherboard 1 is placed is adjusted in parallel to X and Y coordinate axes of each of the probe moving section 4 and the camera moving section 6. The adjustment of the position of the alignment stage 11 is carried out with use of an optical camera 12, which is provided above the alignment stage 11 for the purpose of checking a position of the motherboard 1.

The probe moving section 4 is slidably provided on guide rails 13a which are provided on the outside of the alignment stage 11. Further, guide rails 13b and 13c are also provided on a main body side of the probe moving section 4, and a mount section 14a is provided so as to be movable along these guide rails 13 in X, Y, and Z coordinate directions. On the mount section 14a, a probe section 3 corresponding to the liquid crystal panel 2.

The camera moving section 6 is slidably provided on guide rails 13d which are provided on the outside of the probe moving section 4. Further, guide rails 13e and 13f are also provided on a main body of the camera moving section 6, and mount sections 14b, 14c, and 14d are provided at respective three positions so as to be separately movable along these guide rails 13 in X, Y, and Z coordinate directions.

A macro measurement infrared camera 5a is mounted on the mount section 14c. A micro measurement infrared camera 5b is mounted on the mount section 14b. An optical camera 16 is mounted on the mount section 14d.

The macro measurement infrared camera 5a is an infrared camera which is capable of macro measurement in which a field of view is widened to about 520 mm×405 mm. In order to widen the field of view, the macro measurement infrared camera 5a is constituted by, for example, four infrared cameras. That is, a field of view of each infrared camera of the macro measurement infrared camera is about one fourth of the motherboard 1.

The micro measurement infrared camera 5b is an infrared camera which is capable of micro measurement in which a high-resolution image can be captured although a field view of is small with about 32 mm×24 mm.

Note that it is possible to add a mount section to the camera moving section 6 so that a laser irradiation device for correcting a defect portion can be mounted on the mount section. Having the laser irradiation device makes it possible to carry out, successively after a position of a defect part is detected, defect correction by irradiating the defect part with laser light.

The probe moving section 4 and the camera moving section 6 are provided on the respective different guide rails 13a and 13b. This allows the probe moving section 4 and the camera moving section 6 to move above the alignment stage 11 in an X coordinate direction without being interfered by each other. This allows the infrared cameras 5a and 5b and the optical camera 16 to move to a position above a liquid crystal panel 2 while the probe section 3 is in contact with the liquid crystal panel 2.

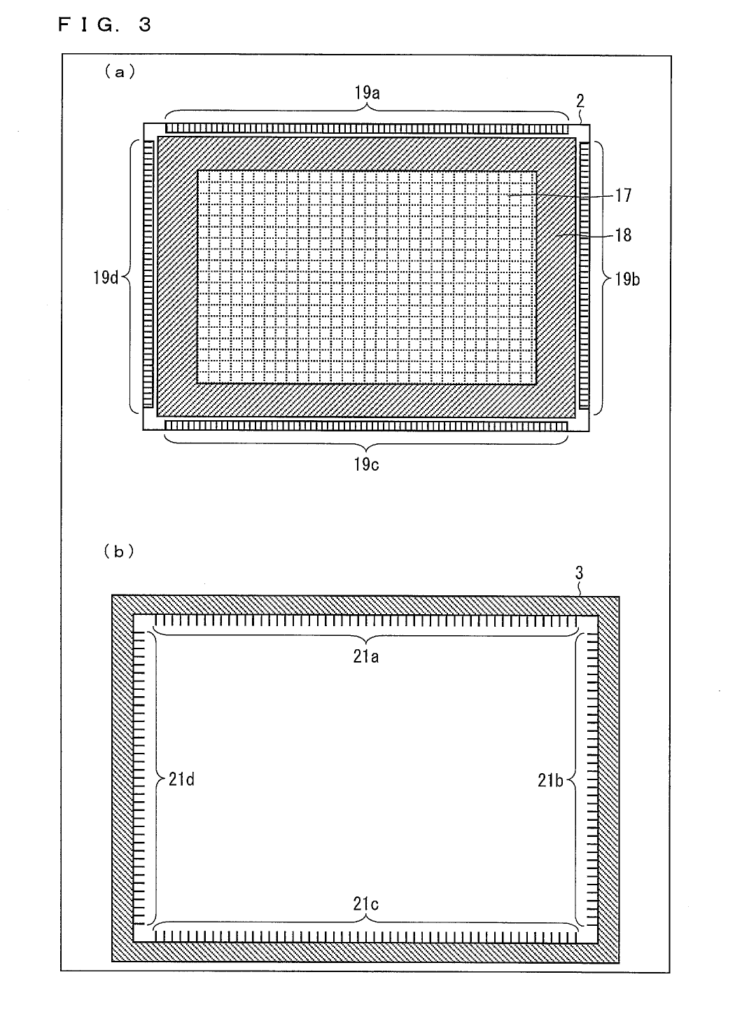

(a) of FIG. 3 is a plan view of one of the plurality of liquid crystal panels 2 provided on the motherboard 1. Each liquid crystal panel 2 includes, as illustrated in (a) of FIG. 3, (i) a pixel section 17 in which TFTs are provided at intersections of scanning lines and signal lines and (ii) a drive circuit section 18 for driving the scanning lines and the signal lines. Terminal sections 19a through 19d are provided at edges of the liquid crystal panel 2, and are connected with wiring of the pixel section 17 or of the drive circuit section 18.

Note that the liquid crystal panel 2 is prepared by forming, on a transparent substrate, a gate electrode, a semiconductor film, a source electrode, a drain electrode, a protective film, and a transparent electrode. The following description will discuss an example of a specific method for manufacturing the liquid crystal panel 2.

First, metal films such as, for example, a titanium film, an aluminum film, and a titanium film are formed in order by sputtering over the entire transparent substrate. Subsequently, patterning is carried out by photolithography so as to form gate wiring, a gate electrode, and capacitor wiring in a thickness of, for example, about 4000 Å.

Next, throughout the substrate on which the gate wiring, the gate electrode, and the capacitor wiring have been formed, a silicon nitride film or the like is formed by, for example, plasma CVD (Chemical Vapor Deposition), thereby forming a gate insulating film in a thickness of about 4000 Å.

Further, an intrinsic amorphous silicon film and an n+ amorphous silicon film which is doped with phosphorous are formed in succession by plasma CVD throughout the substrate on which the gate insulating film has been formed. Then, these silicon films are patterned by photolithography into an island shape on the gate electrode, thereby forming a semiconductor film which is made up of the intrinsic amorphous silicon layer with a thickness of about 2000 Å and the n+ amorphous silicon layer with a thickness of about 500 Å which are stacked on top of each other.

Then, an aluminum film, a titanium film, and the like are formed by sputtering throughout the substrate on which the semiconductor film has been formed. Subsequently, patterning is carried out by photolithography so as to form source wiring, a source electrode, a conductive film, and a drain electrode, each in a thickness of about 2000 Å.

Next, the n+ amorphous silicon layer of the semiconductor film is etched with use of the source electrode and the drain electrode as a mask, so that a channel section is patterned. Thus, a TFT is formed.

Further, the entire substrate on which the TFT has been formed is coated with, for example, an acrylic photosensitive resin by spin coating, and the coated photosensitive resin is exposed via a photomask. Then, the exposed photosensitive resin is developed, so that an interlayer insulating film is formed in a thickness of about 2 μm to 3 μm on the drain electrode. Subsequently, a contact hole is formed in the interlayer insulating film for each pixel.

Next, an ITO film is formed by sputtering over the entire substrate on the interlayer insulating film, and then patterned by photolithography to thereby form a transparent electrode in a thickness of about 1000 Å.

In this way, the liquid crystal panel 2 (semiconductor substrate) can be prepared.

Note that the example of the method for manufacturing the liquid crystal panel 2 can be applied to the motherboard 1 (semiconductor substrate). By using a large-sized transparent substrate and by applying the above-described steps, a gate electrode and the like are formed in a region in which a plurality of (for example, eight in (b) of FIG. 1) liquid crystal panels are formed, and then a transparent electrode is formed. Subsequently, a wiring defect inspecting method described below is carried out so as to repair a product having a defect detected and, if necessary, the wiring defect inspecting method is carried out again to thereby manufacture a non-defective product that has no defect. A product having no defect detected is determined as a non-defective product at this stage. Then, a subsequent step is carried out in which, for example, each liquid crystal panel is separated from the motherboard. Thus, manufacture of one liquid crystal panel is completed. Examples of a method for repairing a defect include, but not limited to, a method in which a short-circuited part is cut off by laser irradiation.

(b) of FIG. 3 is a plan view of the probe section 3 for causing to be conductive with the terminal sections 19a through 19d of the liquid crystal panel 2. The probe section 3 has a frame shape that is substantially equal in size to the liquid crystal panel 2 illustrated in (a) of FIG. 3. The probe section 3 includes (i) a plurality of probes 21a, (ii) a plurality of probes 21b, (iii) a plurality of probes 21c, and (iv) a plurality of probes 21d, respectively corresponding to the respective terminal sections 19a through 19d of the liquid crystal panel 2.

Each probe 21 of the plurality of probes 21a through 21d can individually be connected, via a switching relay (not shown), to the resistance measuring section 8 and the voltage applying section 9 illustrated in (a) of FIG. 1. This makes it possible to (i) selectively connect, to the probe 3, a plurality of wirings connected to the terminal sections 19a through 19d or (ii) collectively connect the plurality of wirings to the probe 3.

Further, since the probe section 3 has the frame shape substantially equal in size to the liquid crystal panel 2, alignment between (i) the terminal sections 19a through 19d and (ii) the probes 21a through 21d can be carried out by checking an inside of the frame of the probe section 3 with use of the optical camera 16.

As described above, the wiring defect inspecting apparatus 100 in accordance with the present embodiment includes the probe section 3, and the resistance measuring section 8 connected to the probe section 3. A resistance of each wiring, a resistance between adjacent wirings, and the like can be measured by causing the probe section 3 to be conductive with the liquid crystal panel 2.

Further, the wiring defect inspecting apparatus 100 in accordance with the present embodiment includes the probe section 3, the voltage applying section 9 connected to the probe section 3, and the infrared cameras 5a and 5b. A position of a defect part can be identified by (i) applying a voltage to a wiring or between wirings of the liquid crystal panel 2 via the probe section 3 so that an electric current is applied to the defect part and (ii) measuring, by using the infrared cameras 5a and 5b, heat which is generated from the defect part due to the application of the electric current.

Therefore, according to the wiring defect inspecting apparatus 100 in accordance with the present embodiment, it is possible to carry out both resistance inspection and infrared inspection by using a single inspecting apparatus.

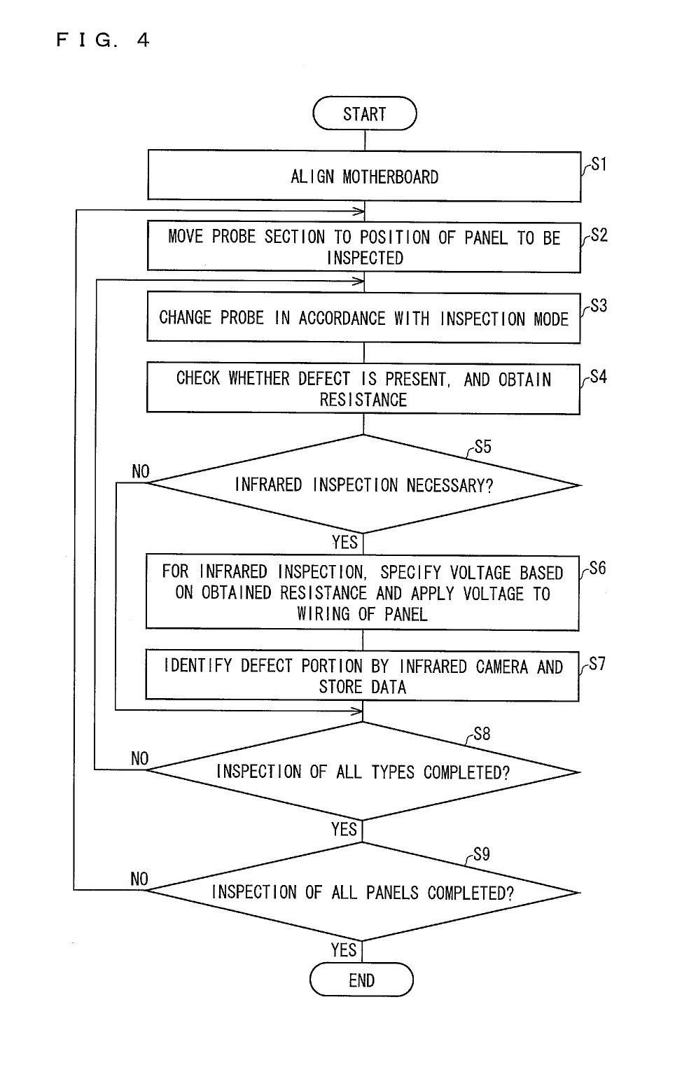

FIG. 4 is a flowchart of a wiring defect inspecting method which is carried out with use of the wiring defect inspecting apparatus 100 in accordance with the present embodiment. In a wiring defect inspecting method in accordance with the present embodiment, the plurality of liquid crystal panels 2 formed on the motherboard 1 are sequentially inspected for a wiring defect in accordance with steps S1 through S9, as shown in FIG. 4.

At step S1, the motherboard 1 is placed on the alignment stage 11 of the wiring defect inspecting apparatus 100 and a position of the motherboard 1 is adjusted so as to be in parallel with X and Y coordinate axes.

At step S2, with use of the probe moving section 4, the probe section 3 is moved to a position above a liquid crystal panel 2 to be inspected, and the probes 21a through 21d are brought in contact with the terminal sections 19a through 19d of the liquid crystal panel 2.

At step S3, in accordance with various defect modes, (i) a wiring or wirings, a resistance of or between which is to be inspected, is/are selected and (ii) probes 21 to be conductive with the liquid crystal panel 2 are changed with another ones.

At step S4 (resistance measuring step), resistance inspection is carried out. At step S4, the resistance of the selected wiring or the resistance between the selected wirings is measured, and whether or not a defect is present is inspected by comparing the resistance with a resistance of a case where no defect is present.

In a case where it is determined in the resistance inspection that a defect is present, the measured resistance is stored in the data storage section 10.

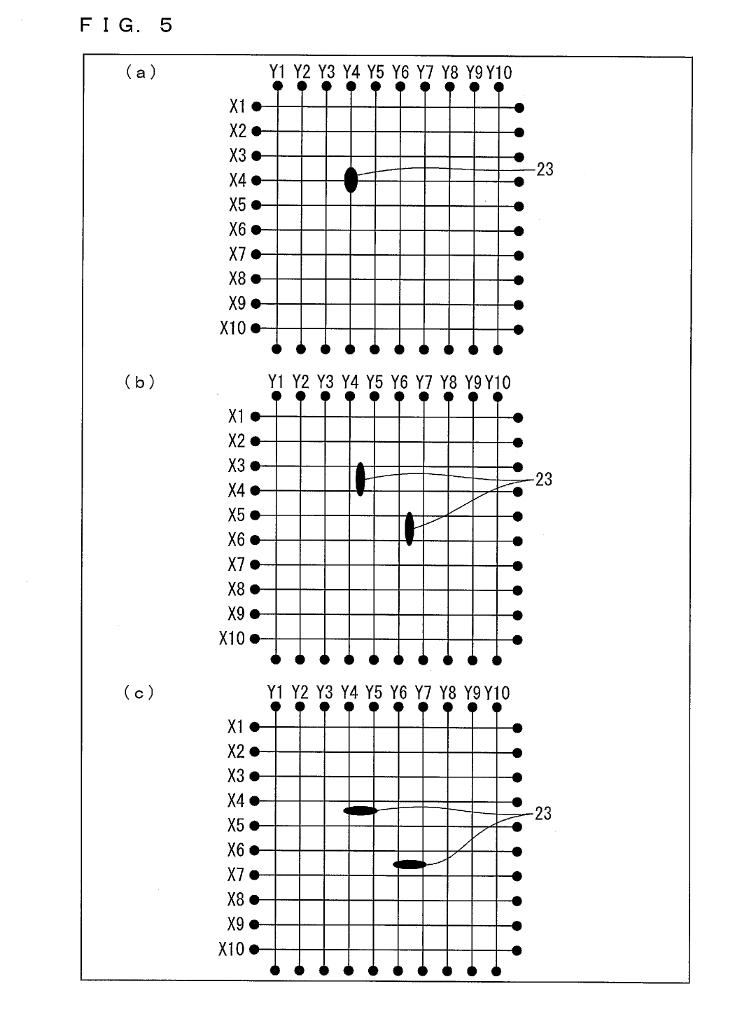

(a) through (c) of FIG. 5 schematically show examples of a position of a defect part 23 (wiring short-circuited part) in the pixel section 17.

(a) of FIG. 5 illustrates a defect part 23 at which a wiring X and a wiring Y are short-circuited in a liquid crystal panel in which, like a scanning line and a signal line, a wiring X and a wiring Y intersect with each other so that one of the wiring X and the wiring Y is on top of the other. The probes 21 to be conductive with the liquid crystal panel 2 are changed to a combination of one of the probes 21a and one of the probes 21d or a combination of one of the probes 21b and one of the probes 21c illustrated in FIG. 3, and a resistance is measured between one of the wirings X1 through X10 and one of the wirings Y1 through Y10. This makes it possible to determine whether or not a defect part 23 is present and identify a position of the defect part 23.

(b) of FIG. 5 illustrates a defect part 23 which is a short circuit between adjacent wirings X like, for example, a scanning line and a storage capacitor wiring. A wiring having a defect part 23 of this kind can be identified in such a manner that (i) the probes 21 to be conductive with the liquid crystal panel 2 are changed to a combination of an odd-numbered one of the probes 21b and an even-numbered one of the probes 21d, and (ii) a resistance between adjacent ones of the wirings X1 through X10 is measured. In a case where a result of the inspection reveals that a defect is present, the measured resistance is stored in the data storage section 10.

(c) of FIG. 5 illustrates a defect part 23 which is a short circuit between adjacent ones of the wirings Y like, for example, a signal line and a storage capacitor wiring. A wiring having a defect part 23 of this kind can be identified in such a manner that (i) the probes 21 to be made conductive with the liquid crystal panel 2 are changed to a combination of an odd-numbered one of the proves 21a and an even-numbered one of the proves 21c, and (ii) a resistance between adjacent ones of the wirings Y1 through Y10 is measured. In a case where a result of the inspection reveals that a defect is present, the measured resistance is stores in the data storage section 10.

At step S5, whether or not to carry out infrared inspection is determined on the basis of the presence or absence of a defect part 23 inspected at step S4. In a case where a defect part 23 is present, the wiring defect inspecting method proceeds to step S6 in order to carry out the infrared inspection. In a case where no defect part 23 is present, the wiring defect inspecting method proceeds to step S8 without carrying out the infrared inspection. Step S5 is, in effect, part of the resistance measuring step.

For example, in a case where, as illustrated in (a) of FIG. 5, a defect part 23 is present at a position where a wiring X and a wiring Y intersect with each other, an abnormality is detected in the wiring X4 and the wiring Y4 by resistance inspection between wirings. Thus, a position of the defect part 23 can be detected as well as the presence of the defect part 23. As such, in the case of the defect part 23 illustrated in (a) of FIG. 5, it is not always necessary to identify (step S6) the position of the defect part 23 by infrared inspection. That is, in a case where resistance inspection is carried out with respect to every combination of a wiring X and a wiring Y, the position of the defect part can also be identified by the resistance inspection. Accordingly, the infrared inspection is unnecessary. However, since the number of combinations of a wiring X and a wiring Y is enormous, the resistance inspection takes a long time. For example, a full-high definition liquid crystal panel has 1080 wirings X and 1920 wirings Y, so that the total number of combinations is about 2,070,000. Carrying out resistance inspection for each of the combinations results in a long takt time and a significant decrease in inspection performance, and is therefore impractical. In view of this, by grouping all of the combinations of a wiring X and a wiring Y into a plurality of groups and carrying out resistance inspection for each of the groups, it is possible to reduce the number of the resistance inspection. For example, in a case where resistance inspection is carried out between (i) a group made up of all of the wirings X and (ii) a group made up of all of the wirings Y, the number of the resistance inspection is only one. In this case, however, the resistance inspection allows detection of a short circuit between wirings but does not allow identification of a position of the short circuit. This makes it necessary to identify the position of the defect part 23 by infrared inspection.

On the other hand, in a case where a defect part 23 is present between adjacent wirings as illustrated in (b) of or (c) of FIG. 5, it is possible to identify a position of the defect part as being between a pair of wirings, for example, between the wiring X3 and the wiring X4. However, it is not possible to identify the position of the defect part 23 in a length direction of each of the wirings. As such, it is necessary to identify the position of the defect part 23 by infrared inspection.

Resistance inspection between adjacent wirings takes a long time since the number of the resistance inspection is enormous. For example, in the case of the full-high definition liquid crystal panel, the number of resistance inspection between adjacent ones of the wirings X is 1079 and resistance inspection between adjacent ones of the wirings Y is 1919. In a case where resistance inspection is carried out between adjacent ones of the wirings X as illustrated in (b) of FIG. 5, it is possible to reduce the number of the resistance inspection to only one by carrying out the resistance inspection between (i) all the odd-numbered ones of the wirings X and (ii) all the even-numbered ones of the wirings X. In a case where resistance inspection is carried out between adjacent ones of the wirings Y as illustrated in (c) of FIG. 5, it is possible to reduce the number of the resistance inspection to only one by carrying out the resistance inspection between (i) all the odd-numbered ones of the wirings Y and (ii) all the even-numbered ones of the wirings Y. However, the resistance inspection allows detection of a short circuit between wirings but does not allow identification of a position of the short circuit. This makes it necessary to identify the position of the defect part 23 by infrared inspection.

At step S6 (heat generating step), infrared inspection is carried out with respect to a liquid crystal panel 2 which has been determined to need infrared inspection.

A feature of the present invention resides in that (i) a voltage is set on the basis of the resistance stored in the data storage section 10 at step S4, and (ii) the voltage thus set is applied by the voltage applying section 9 to the liquid crystal panel 2.

Specifically, in the present embodiment, a voltage V (volt) that is in proportion to a square root of the resistance obtained at step S4 is applied to the liquid crystal panel 2. That is, at step S6, the voltage V (volt) is determined by the formula (1):

[Math 1]

V−k×√(R) (1)

where k is a constant and R is a resistance (ohm).

Note that an amount J (joule) of heat generated per time is represented by the following formula (2):

[Math 2]

J=W×T=W=V×I=I²×R=V²/R (2)

where W is electric power consumption (watt), T is time (second), and I is an electric current (ampere). Accordingly, on the basis of the formulae (1) and (2), the amount J of heat generated per unit time is represented by the following formula (3):

[Math 3]

J=V²/R=[k×√9R]²/R=k²=constant (3)

That is, based on the formula (1), the voltage V (volt), which is in proportion to the square root of the resistance, is applied to the liquid crystal panel 2. This allows the amount of heat generated per unit time to be constant.

Therefore, although a resistance of a short-circuited path including a defect part 23 significantly varies depending on, for example, the type of the substrate or the cause (e.g., a position on the substrate where the defect part 23 is present) of the short circuit, an amount of heat generated per unit time can be made constant by carrying out step S6 of the present embodiment.

Voltage adjustment at step S6 is carried out by the voltage applying section 9 under the control of the main control section 7 illustrated in FIG. 1.

At step S7 (position identifying step), an image of the defect part 23 is captured with use of an infrared camera in order to detect infrared light from the defect part 23 which generates heat due to an electric current generated by application of the voltage. In the present embodiment, the macro measurement infrared camera 5a and the micro measurement infrared camera 5b are provided, and a position of the defect part 23 is identified by initially using, if necessary, by scanning, the macro measurement infrared camera 5a, which is capable of accommodating a wide area of the liquid crystal panel 2 within the field of view. Subsequently, if necessary, the vicinity of a heat-generating part may be measured with use of the micro measurement infrared camera 5b. Since the position of the heat-generating part has been identified by the macro measurement infrared camera 5a, the micro measurement infrared camera 5b can be moved so that the heat-generating part is positioned within the field of view of the micro measurement infrared camera 5b. This makes it possible to (i) identify coordinates of the position of the defect part 23 or (ii) measure necessary information (shape or the like) for correction. Note that, although in the image capturing is carried out in two stages with use of the macro measurement infrared camera 5a and the micro measurement infrared camera 5b in the present embodiment, the present invention is not limited to this. It is possible to carry out the image capturing in a single stage by using a single infrared camera, or carry out an image capturing step as described later in Modified example.

Note, here, that the short-circuited path is constituted by a wiring part and the defect part 23. Accordingly, an amount J of heat generated from the short-circuited path is made up of an amount J₁ of heat generated from the wiring part and an amount J₂ of heat generated from the defect part 23.

Then, the following matters (a) through (c) can be said. (a) In a case where the resistance of the defect part 23 is relatively small, the amount J₂ of heat generated from the defect part 23 is small. However, since the amount J of heat generated from the short-circuited path is constant as described above, the small amount J₂ of heat generated from the defect part 23 results in a large amount J₁ of heat generated from the wiring part. Accordingly, the wiring part that generates much heat is easily recognizable in the infrared image. By further analyzing the recognized part so as to identify a part where wirings are short-circuited, it is possible to detect the defect part 23.

(b) In a case where the resistance of the defect part 23 is relatively large, the amount J₂ of heat generated from the defect part 23 is large. In this case, since the amount J of heat generated from the short-circuited path is constant as described above, the large amount J₂ of heat generated from the defect part 23 results in a small amount J₁ of heat generated from the wiring part. Accordingly, the defect part 23 that generates much heat is easily recognizable in the infrared image.

(c) In a case where the resistance of the defect part 23 is neither small nor large, the defect part 23 and the wiring part generate heat to a similar extent, since the amount J of heat generated from the short-circuited path is constant as described above. Accordingly, both the defect part 23 and the wiring portion can easily be recognized from the infrared image.

As is clear from (a) through (c), either one of the defect part 23 or the wiring portion generates sufficient heat. As such, in the infrared image picked up, a temperature of the defect part 23 or the wiring portion to which an electric current is applied appears higher than the vicinity of the defect part 23 or the wiring portion. This allows the position of the defect part 23 to be easily identified. The position thus identified is stored in the data storage section 10.

At step S8, with respect to the liquid crystal panel 2 under inspection, it is determined whether or not all inspections of various defect modes have been completed.

In a case where there is an uninspected defect mode, the wiring defect inspecting method returns to step S3. Then, connection of the probe section 3 is changed in accordance with the next defect mode, and defect inspection is repeated. Note that a defect mode means a type of a defect part 23 as illustrated in FIG. 5. FIG. 5 shows three defect modes, i.e., a defect mode of a short-circuiting between a wiring X and a wiring Y as illustrated in (a) of FIG. 5, a defect mode of a short-circuiting between wirings X as illustrated in (b) of FIG. 5, and a defect mode of a short circuiting between wirings Y as illustrated in (c) of FIG. 5.

At step S9, with respect to the motherboard 1 under inspection, it is determined whether or not defect inspection of all of the liquid crystal panels 2 has been completed. In a case where there is still an uninspected liquid crystal panel 2, the wiring defect inspecting method returns to step S2. Then, the probe section is moved to the next liquid crystal panel 2 to be inspected, and the defect inspection is repeated.

### Advantageous Effects of the Present Embodiment

According to the present embodiment, whether or not a defect is present is determined by resistance inspection, and, in a case where it is determined that a defect is present, a resistance of a short-circuited path on a liquid crystal panel 2 is obtained. Further, a voltage specified in accordance with the resistance is applied to the liquid crystal panel 2. This causes either one of the defect part 23 or the wiring portion to generate sufficient heat. This allows a position of the defect to be easily detected during infrared inspection.

Further, use of the wiring defect inspecting method in accordance with the present embodiment eliminates a situation where an insufficient amount of heat generated from the defect part 23 and the wiring portion prevents detection of the position of the defect part 23. Further, the use of the wiring defect inspecting method in accordance with the present embodiment eliminates a situation where the defect part 23 is burned and cut off by being applied too high a voltage. This allows the position of the defect to be easily detected during infrared inspection.

### Modified Example

The present embodiment has described an arrangement as illustrated in FIG. 1 in which the resistance measuring section 8 for measuring a resistance of wiring is provided. Note, however, that the present invention is not limited to this, and can employ an arrangement in which (i) a data taking-in section (not shown) for taking in a pre-measured resistance of the wiring is provided, and (ii) the main control section 7 controls, on the basis of the resistance taken in by the data taking-in section, a voltage which is applied for generating heat.

According to the arrangement, resistance measurement is carried out in a different apparatus. This allows the resistance measurement and the image capturing by the infrared camera to be operated in parallel with each other, so that the performance can be improved.

### Embodiment 2

Another embodiment in accordance with the present invention is described below.

In the present embodiment, the same apparatus as used in embodiment 1 is used so that a voltage V (volt) applied is set to a value different from that of the voltage V applied in Embodiment 1.

In Embodiment 1 described above, at step S6, a voltage V (volt) that is in proportion to a square root of the resistance obtained at step S4 is applied to the liquid crystal panel 2. By contrast, in the present embodiment, a voltage V (volt) that is in proportion to the resistance obtained at step S4 is applied to the liquid crystal panel 2 ((b) of FIG. 1 and FIG. 2).

Specifically, at step S6 of the present embodiment, the voltage V (volt) applied is set by the following formula (4):

[Math 4]

V=m×R (4)

where m is a constant and R is a resistance (ohm). Note, here, that an electric current I (ampere) is found by the following formula (5):

[Math 5]

I=V/R=(m×R)/R=m (5).

That is, by appropriately setting the voltage applied, it is possible to make the electric current constant.

Note, here, that the resistance R of the wiring formed on the substrate is found by the following formula (6):

[Math 6]

R=ρ×L/A (6)

where ρ is an electric resistivity, L is a wiring length (meter), and A is a cross-sectional area (square meter). The electric resistivity ρ and the cross-sectional area A are constants which are prefixed in accordance with a type and a location of the wiring. Accordingly, a resistance R/L=ρ/A of the wiring per unit length is also a constant. That is, a resistance r(i) per unit length of a wiring i (i is a number given for each type and location of the wiring) is represented by the following formula (7):

[Math 7]

r(i)=ρ(i)/A(i)=constant (7)

where ρ is an electric resistivity, and A(i) is a cross-sectional area of the wiring i.

Accordingly, the amount of heat generated from the wiring i per unit length of the wiring i is represented by the following formula (8) on the basis of the formulae (2), (5), and (7):

[Math 8]

W(i)=[²×r(i)=m²×r(i)=constant (8)

where W(i) is an amount of heat generated from the wiring i.

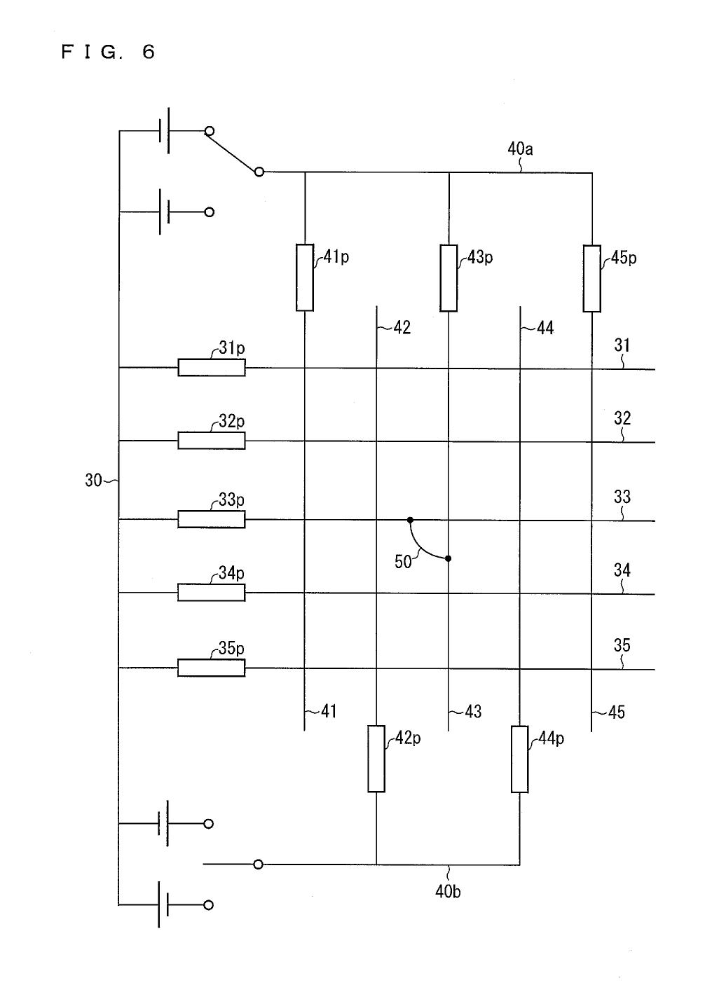

FIG. 6 is a view for illustrating a short-circuited path, and is an example of an electric wiring diagram of a thin-film transistor substrate. The thin-film transistor substrate illustrated in FIG. 6 is a substrate having a total of 5×5 pixels and constituted by a glass substrate, on which scanning lines (wirings) 31 through 35 and signal lines (wirings) 41 through 45 are arranged in a grid pattern. A thin-film transistor (not shown) and a transparent pixel electrode (not shown) are connected with each other at each of the intersections between the scanning lines 31 through 35 and the signal lines 41 through 45. The liquid crystal panel is obtained by placing the thin-film transistor substrate and a common electrode substrate (not shown) in parallel with each other and sealing a gap between the thin-film transistor substrate and the common electrode substrate with liquid crystals. As illustrated in FIG. 6, the thin-film transistor substrate is connected, in common and via a common line 30, to end sections of drawing lines 31p through 35p of the scanning lines so as to prevent electrostatic breakdown. The signal lines have the same arrangement. In the thin-film transistor substrate illustrated in FIG. 6, a short-circuited portion 50 is formed between the scanning line 33 and the signal line 43. In a case where the short-circuited path of the thin-film transistor substrate is divided into the drawing line 33p→the scanning line 33→the short-circuited portion 50→the signal line 43→the drawing line 43p, an amount of heat generated from the scanning line 33 per unit length and an amount of heat generated from the signal line 43 per unit length can each be made constant.

Accordingly, by appropriately predetermining the constant m, it is possible to stably recognize the scanning line 33 and the signal line 43 based on the infrared image, regardless of an intensity of the electric resistance of the short-circuited portion.

By further analyzing the recognized wiring part so as to identify a part where the scanning line 33 and the signal line 43 are short circuited, it is possible to identify the short-circuited portion. Since an amount of heat generated from the short-circuited portion is large in a case where the resistance of the short-circuited portion is high, the short-circuited portion can easily be identified from the infrared image.

Further, in order to determine the voltage on the basis of the resistance of the wiring, the main control section 7 may carry out a process of calculating the formula (1) or the formula (4) whenever such need arises. Alternatively, the main control section 7 may determine the voltage on the basis of a resistance by, whenever such need arises, referring to a table in which a relation between a resistance and a voltage has been stored in advance.

As described above, the wiring defect inspecting method and the wiring defect inspecting apparatus of the present embodiment also make it possible to recognize a defect on the basis of an infrared image, as in Embodiment 1.

The present invention is not limited to the above-described embodiments. A person skilled in the art can make various modifications of the present invention within the scope of the claims. In other words, new embodiment can be derived from a combination of technical means appropriately modified within the scope of the claims. In other words, the embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### CONCLUSION OF THE PRESENT INVENTION

A wiring defect inspecting method in accordance with the present invention includes the steps of: (a) measuring a resistance of wiring included in a semiconductor substrate, thereby determining whether or not the semiconductor substrate has a wiring short-circuited part; (b) causing a short-circuited path to generate heat by applying, to the short-circuited path, a voltage specified on the basis of the resistance measured in the step (a), the short-circuited path including the wiring short-circuited part of the semiconductor substrate which has been determined to have the wiring short-circuited part in the step (a); and (c) capturing, with use of an infrared camera, an image of the short-circuited path which has generated heat in the step (b) and identifying a position of the wiring short-circuited part on the basis of information of the image.

According to the above arrangement, the voltage specified on the basis of the resistance obtained in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, in addition to the above arrangement, an embodiment of the wiring defect inspecting method in accordance with the present invention is preferably arranged such that the voltage applied to the wiring in the step (b) is adjusted so as to increase as the resistance increases.

This makes an amount of heat generated from the semiconductor substrate (leak defect substrate) constant.

Further, in addition to the above arrangement, an embodiment of the wiring defect inspecting method in accordance with the present invention is preferably arranged such that the voltage applied to the wiring in the step (b) is in proportion to a square root of the resistance.

This makes an amount of heat generated from the semiconductor substrate (leak defect substrate) constant.

Further, instead of the above arrangement, an embodiment of the wiring defect inspecting method in accordance with the present invention is preferably arranged such that the voltage applied to the wiring in the step (b) is in proportion to the resistance.

This arrangement also makes an amount of heat generated from the semiconductor substrate (leak defect substrate) constant.

Further, in order to attain the object, a wiring defect inspecting apparatus in accordance with the present invention is a wiring defect inspecting apparatus including: a data taking-in section for taking in a resistance of wiring included in a semiconductor substrate, the resistance being measured in advance; a voltage applying section for applying a voltage to the wiring; a control section for controlling the voltage applying section; and an infrared camera for detecting infrared rays emitted from the semiconductor substrate which is generating heat in response to the voltage applied under control of the control section, the control section controlling, in accordance with the resistance taken in by the data taking-in section, a value of the voltage applied for causing the wiring to generate heat.

According to the above arrangement, the voltage specified on the basis of the resistance of the wiring measured in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, since resistance measurement is carried out in a different apparatus, the resistance measurement and the image capturing by the infrared camera can be operated in parallel with each other, so that the performance can be improved.

Further, in order to attain the object, a wiring defect inspecting apparatus in accordance with the present invention is a wiring defect inspecting apparatus including: a voltage applying section for applying a voltage to wiring included in a semiconductor substrate; a resistance measuring section for measuring a resistance of the wiring; a control section for controlling the voltage applying section; and an infrared camera for detecting infrared rays emitted from the semiconductor substrate which is generating heat in response to the voltage applied under control of the control section, the control section controlling, in accordance with the resistance measured by the resistance measuring section, a value of the voltage applied for causing the wiring to generate heat.

According to the above arrangement, the voltage specified on the basis of the resistance obtained in advance by the resistance inspection is applied to the semiconductor substrate (leak defect substrate). This makes an amount of heat generated from the semiconductor substrate (leak defect substrate) constant. Accordingly, an increase in temperature can be reliably checked by infrared inspection with use of the infrared camera, so that the short-circuited part can be identified. Further, the arrangement prevents the defect part from being burned and cut off due to application of too high a voltage. This allows the short-circuited part to be identified stably.

Further, since the wiring defect inspecting apparatus itself measures the resistance of the wiring, it is not necessary to separately provide an apparatus for measuring resistance. This allows a reduction in the number of apparatuses.

Further, a method, in accordance with the present invention, for manufacturing a semiconductor substrate is a method for manufacturing a semiconductor substrate, including the steps of: (a) forming, on a substrate, (i) at least one of a gate electrode, a source electrode, and a drain electrode, (ii) wiring connected to the at least one of the gate electrode, the source electrode, and the drain electrode, and (iii) a semiconductor film, thereby forming a semiconductor substrate on which the wiring is provided; (b) measuring a resistance of the wiring included in the semiconductor substrate, thereby determining whether or not the semiconductor substrate has a wiring short-circuited part; (c) causing a short-circuited path to generate heat by applying, to the short-circuited path, a voltage specified on the basis of the resistance measured in the step (b), the short-circuited path including the wiring short-circuited part of the semiconductor substrate which has been determined to have the wiring short-circuited part in the step (b); and (d) capturing, with use of an infrared camera, an image of the short-circuited path which has generated heat in the step (c) and identifying a position of the wiring short-circuited part on the basis of information of the image.

### INDUSTRIAL APPLICABILITY

The present invention can be applied to inspection of a condition of wiring of a semiconductor substrate, such as a liquid crystal panel, which has the wiring.

### REFERENCE SINGS LIST

1 motherboard (semiconductor substrate)
2 liquid crystal panel (semiconductor substrate)
3 probe section
4 probe moving section
5a, 5b infrared camera
6 camera moving section
7 main control section (control section)
8 resistance measuring section
9 voltage applying section
10 data storage section
11 alignment stage
12, 16 optical camera
13a, 13b, 13c, 13d, 13e, 13f guide rail
14a, 14b, 14d, 14d mount section
17 pixel section
18 drive circuit section
19a, 19b, 19c, 19d terminal section
21a, 21b, 21c, 21d probe
23 defect portion (wiring short-circuited part)
30, 40a, 40b common line
31, 32, 33, 34, 35 scanning line
31p, 32p, 33p, 34p, 35p scanning line drawing line
41, 42, 43, 44, 45 signal line
41p, 42p, 43p, 44p, 45p signal line drawing line
50 short-circuited portion
100 wiring defect inspecting apparatus

1. A wiring defect inspecting method comprising the steps of:
(a) measuring a resistance of wiring included in a semiconductor substrate, thereby determining whether or not the semiconductor substrate has a wiring short-circuited part;
(b) causing a short-circuited path to generate heat by applying, to the short-circuited path, a voltage specified on the basis of the resistance measured in the step (a), the short-circuited path including the wiring short-circuited part of the semiconductor substrate which has been determined to have the wiring short-circuited part in the step (a); and
(c) capturing, with use of an infrared camera, an image of the short-circuited path which has generated heat in the step (b) and identifying a position of the wiring short-circuited part on the basis of information of the image.

2. The wiring defect inspecting method as set forth in claim 1, wherein:
the voltage applied to the wiring in the step (b) is adjusted so as to increase as the resistance increases.

3. The wiring defect inspecting method as set forth in claim 2, wherein:
the voltage applied to the wiring in the step (b) is in proportion to a square root of the resistance.

4. The wiring defect inspecting method as set forth in claim 2, wherein:
the voltage applied to the wiring in the step (b) is in proportion to the resistance.

5. A wiring defect inspecting apparatus comprising:
a data taking-in section for taking in a resistance of wiring included in a semiconductor substrate, the resistance being measured in advance;
a voltage applying section for applying a voltage to the wiring;
a control section for controlling the voltage applying section; and
an infrared camera for detecting infrared rays emitted from the semiconductor substrate which is generating heat in response to the voltage applied under control of the control section,
the control section controlling, in accordance with the resistance taken in by the data taking-in section, a value of the voltage applied for causing the wiring to generate heat.

6. (canceled)

7. A method for manufacturing a semiconductor substrate, comprising the steps of:
(a) forming, on a substrate, (i) at least one of a gate electrode, a source electrode, and a drain electrode, (ii) wiring connected to the at least one of the gate electrode, the source electrode, and the drain electrode, and (iii) a semiconductor film, thereby forming a semiconductor substrate on which the wiring is provided;
(b) measuring a resistance of the wiring included in the semiconductor substrate, thereby determining whether or not the semiconductor substrate has a wiring short-circuited part;
(c) causing a short-circuited path to generate heat by applying, to the short-circuited path, a voltage specified on the basis of the resistance measured in the step (b), the short-circuited path including the wiring short-circuited part of the semiconductor substrate which has been determined to have the wiring short-circuited part in the step (b); and
(d) capturing, with use of an infrared camera, an image of the short-circuited path which has generated heat in the step (c) and identifying a position of the wiring short-circuited part on the basis of information of the image.
